(19) United States
(12) Patent Application Publication
(10) Pub. No.: US 2025/0208213 A1
(43) Pub. Date: Jun. 26, 2025

(54) BATTERY MONITORING DEVICE

(71) Applicant: DENSO CORPORATION, Kariya-city (JP)

(72) Inventors: Toshiki KOJIMA, Kariya-city (JP); Takashi INAMOTO, Kariya-city (JP); Masakazu KOUDA, Kariya-city (JP)

(73) Assignee: DENSO CORPORATION, Kariya-city (JP)

(21) Appl. No.: 19/077,356

(22) Filed: Mar. 12, 2025

Related U.S. Application Data
(63) Continuation of application No. PCT/JP2023/032852, filed on Sep. 8, 2023.

(30) Foreign Application Priority Data
Oct. 11, 2022 (JP) 2022-163496

(51) Int. Cl. G01R 31/36; B60L 50/60; B60L 58/10; G01R 31/3842

(52) U.S. Cl. CPC G01R 31/3644; B60L 50/60; B60L 58/10; G01R 31/3842; B60L 2240/547

(57) ABSTRACT

A battery monitoring device includes a wiring board having a portion of a wiring provided on a board surface, a circuit component surface-mounted on the board surface and connected to the wiring, and a connector that electrically connects the wiring board to at least a battery. The connector has a terminal connected to a mounting land which is part of the wiring provided on the board surface, and a connector case in which the terminal is provided. The wiring board is provided with a cutout portion recessed from a surrounding area on a part of a side surface, and at least a part of the connector case is disposed in the cutout portion.

### CROSS REFERENCE TO RELATED APPLICATIONS

The present application is a continuation application of International Patent Application No. PCT/JP2023/032852 filed on Sep. 8, 2023, which designated the U.S. and claims the benefit of priority from Japanese Patent Application No. 2022-163496 filed in Japan filed on Oct. 11, 2022, the entire disclosure of the above application is incorporated herein by reference.

### TECHNICAL FIELD

The present disclosure relates to a battery monitoring device.

### BACKGROUND

An example of a battery monitoring device includes a battery information input terminal electrically connected to a battery status detection member, a battery status monitoring unit to which a battery status detection signal is input via the battery information input terminal, an output terminal that outputs battery status monitoring information corresponding to the battery status detection signal to an external processing device, and a circuit board on which these components are mounted.

### SUMMARY

One disclosed object is to provide a battery monitoring device having a reduced size.

A battery monitoring device disclosed herein is a battery monitoring device that monitors a state of a battery mounted on a vehicle. The battery monitoring device includes a wiring board having a part of wiring provided on a first surface thereof, a circuit component that are surface mounted on the first surface and connected to the wiring, and a connector member for electrically connecting the wiring board and at least the battery, the connector member having a terminal connected to a land that is a part of the wiring provided on the first surface and a housing in which the terminal is provided. The wiring board has a cutout portion on a part of its side surface that is recessed from a surrounding area, and at least a part of the housing is disposed in the cutout portion.

### BRIEF DESCRIPTION OF DRAWINGS

FIG. 1 is a conceptual diagram showing an example of mounting a battery monitoring device;

FIG. 2 is a perspective view showing a schematic configuration of the battery monitoring device;

FIG. 3 is a plan view showing a schematic configuration of a wiring board;

FIG. 4 is a cross-sectional view taken along a line IV-IV of FIG. 3;

FIG. 5 is a cross-section view taken along a line V-V in FIG. 3;

FIG. 6 is a plan view showing a schematic configuration of a wiring board without a connector member attached thereto; and

FIG. 7 is a plan view showing a schematic configuration of a wiring board in a first modified example.

### DETAILED DESCRIPTION

An example of a battery monitoring device includes a battery information input terminal electrically connected to a battery status detection member, a battery status monitoring unit to which a battery status detection signal is input via the battery information input terminal, an output terminal that outputs battery status monitoring information corresponding to the battery status detection signal to an external processing device, and a circuit board on which these components are mounted. Furthermore, the battery monitoring device uses a through-type terminal that penetrates the circuit board as the battery information input terminal.

The battery monitoring device uses a through-type terminal, so that the terminal protrudes in a plate thickness direction of the circuit board. Therefore, the battery monitoring device has a problem in that its size in the plate thickness direction becomes large. Furthermore, in the above respects and in other respects not mentioned, further improvements are required in the battery monitoring device.

One disclosed object is to provide a battery monitoring device having a reduced size.

A battery monitoring device disclosed herein is a battery monitoring device that monitors a state of a battery mounted on a vehicle. The battery monitoring device includes a wiring board having a part of wiring provided on a first surface thereof, a circuit component that are surface mounted on the first surface and connected to the wiring, and a connector member for electrically connecting the wiring board and at least the battery, the connector member having a terminal connected to a land that is a part of the wiring provided on the first surface and a housing in which the terminal is provided. The wiring board has a cutout portion on a part of its side surface that is recessed from a surrounding area, and at least a part of the housing is disposed in the cutout portion.

In this manner, the terminal of the battery monitoring device is connected to a land provided on the first surface of the wiring board. In addition, at least a portion of the housing of the battery monitoring device is disposed in a cutout portion provided on a side surface of the wiring board. Therefore, the battery monitoring device can be made smaller in size in the thickness direction of the wiring board.

The disclosed aspects in this specification adopt different technical solutions from each other in order to achieve their respective objectives. Reference numerals in parentheses described in claims and this section exemplarily show corresponding relationships with parts of embodiments to be described later and are not intended to limit technical scopes. The objects, features, and advantages disclosed in this specification will become apparent by referring to following detailed descriptions and accompanying drawings.

As follows, multiple embodiments for implementing the present disclosure will be described with reference to the drawings. In each embodiment, portions corresponding to those described in the preceding embodiment are denoted by the same reference numerals, and redundant descriptions will be omitted in some cases. In each of the embodiments, when only a part of the configuration is explained, the other part of the embodiment can be referred to the other embodiment explained previously and applied.

Hereinafter, three directions perpendicular to each other are denoted as an X direction, a Y direction, and a Z direction. A plane defined by the X direction and the Y direction is denoted as an XY plane. Unless otherwise specified, a plan view refers to a drawing viewed from the Z direction.

### Battery Pack

First, a battery pack 300 in which a battery monitoring device 100 is mounted will be described. The battery pack 300 is disposed below a vehicle seat. Furthermore, the battery pack 300 may be disposed in other locations, such as in the engine compartment, the trunk, or under the floor of the vehicle. The vehicle is an electric vehicle or a hybrid vehicle that runs on power stored in a battery pack 300. That is, the battery pack 300 is mounted on the vehicle as a driving power source for the vehicle.

The battery pack 300 includes a plurality of battery modules 200 each including a plurality of battery cells. Each battery cell is composed of a lithium ion secondary battery, a nickel-hydrogen secondary battery, or the like. The lithium ion secondary battery is a secondary battery that uses lithium as a charge carrier, and may include not only general lithium ion secondary batteries that use a liquid electrolyte, but also so-called all-solid-state batteries that use a solid electrolyte. The battery module 200 corresponds to a battery.

The battery pack 300 (the battery module 200) stores electric power for driving a vehicle's traction motor in battery cells, and is configured to be able to supply electric power to the traction motor. The battery pack 300 is charged by receiving power generated by the traction motor during regenerative power generation by the traction motor, such as during vehicle braking. The traction motor corresponds to an electric motor that drives the vehicle.

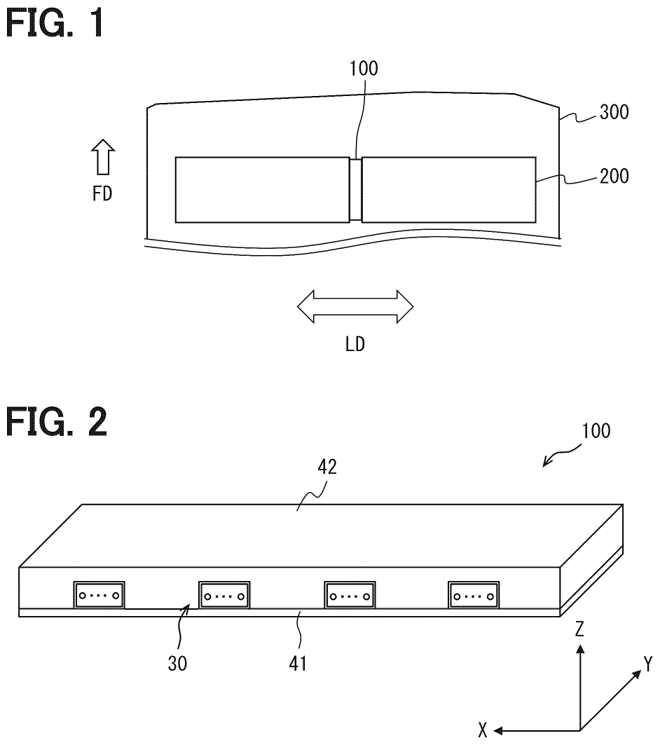

As shown in FIG. 1, a battery pack 300 includes a plurality of battery modules 200, a plurality of battery monitoring devices 100, and a battery housing that houses these components. The battery pack 300 has two battery modules 200 arranged along a left-right direction LD of the vehicle. However, the battery pack 300 may have a plurality of battery modules 200 arranged along a forward direction FD of the vehicle. Furthermore, the battery pack 300 may have three or more battery modules 200 arranged along the left-right direction LD of the vehicle. Therefore, the battery pack 300 may have a plurality of battery modules 200 arranged in two or more columns and two or more rows. The multiple battery modules 200 may be arranged in a state rotated by 90° from the state shown in FIG. 1. In other words, the battery pack 300 may have a plurality of battery modules 200 and the battery monitoring device 100 arranged side by side along the forward direction FD. One battery monitoring device 100 may be provided for a plurality of battery modules 200, or one battery monitoring device 100 may be provided for one battery module 200. The size of the battery pack 300 in the left-right direction LD is limited due to a side impact protection requirement. The forward direction FD is parallel to the front-rear direction of the vehicle.

The battery pack 300 is connected to a vehicle control device, a power control unit, and the like. The power control unit performs bidirectional power conversion between the battery pack 300 and the traction motor in accordance with a control signal from the vehicle control device. The power control unit includes, for example, an inverter that drives the traction motor, and a converter that boosts the DC voltage supplied to an inverter to an output voltage of the battery pack 300 or higher.

The vehicle control device includes a CPU, a ROM, a RAM, and input/output ports for inputting and outputting various signals. The CPU loads the program stored in the ROM into the RAM and executes it. The programs stored in the ROM contain instructions for the processing of the vehicle control device. The vehicle control device, for example, acquires battery information, which will be described later, from the battery monitoring device 100 and controls the power control unit. The vehicle control device controls the driving of the traction motor and the charging and discharging of the battery pack 300.

### Battery Monitoring Device

The battery monitoring device 100 includes a wiring board 10, circuit components 21 and 22, a connector 30, a base 41, a cover 42, and the like. The battery monitoring device 100 is a device that monitors a state of a battery module 200 (battery cell) mounted on the vehicle. The battery monitoring device 100 is provided in the battery pack 300.

### Wiring Board and Circuit Components

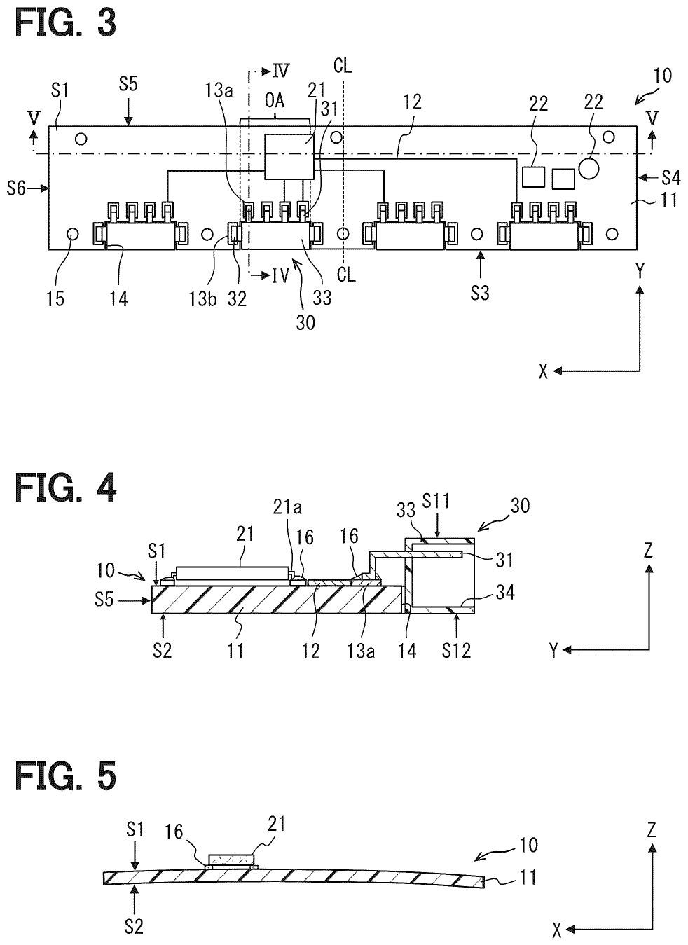

As shown in FIGS. 3 and 4, the wiring board 10 has an insulating substrate 11 made of insulating material such as resin as a main component, and a conductive wiring 12 made of metal such as copper as a main component. In the present embodiment, as an example of the wiring board 10, a multi-layer board in which wiring 12 is laminated with an insulating substrate 11 interposed therebetween is used. That is, the wiring board 10 has wiring 12 formed on a plurality of insulating layers that constitute the insulating substrate 11. The wiring board 10 is constructed by laminating a plurality of insulating layers. The wiring board 10 may be, for example, a board in which several insulating layers are laminated. However, the wiring board 10 is not limited to a multi-layer board.

The wiring board 10 has a substantially rectangular shape (substantially oblong shape) in a plan view. A longitudinal direction of the wiring board 10 coincides with the X direction, and a lateral direction coincides with the Y direction. The wiring board 10 has a board front surface S1 and a board back surface S2 opposite to the board front surface S1. The board front surface S1 and the board back surface S2 are surfaces approximately parallel to the XY plane. The board front surface S1 and the board back surface S2 are each substantially rectangular. Hereinafter, the longitudinal direction of the wiring board 10 will also be referred to simply as the longitudinal direction, and the lateral direction of the wiring board 10 will also be referred to simply as the lateral direction. The board front surface S1 corresponds to one surface, and the board back surface S2 corresponds to the opposite surface.

The wiring board 10 has side surfaces S3 to S6 connected to the board front surface S1 and the board back surface S2. The wiring board 10 has, as the side surfaces S3 to S6, the short side surfaces S4 and S6 extending along the lateral direction and the long side surfaces S3 and S5 extending along the longitudinal direction. The side surfaces S3 to S6 are surfaces that are approximately perpendicular to the XY plane. In addition, a center line CL in FIG. 3 is a line that passes through the center in the longitudinal direction and extends along the lateral direction. The center line CL is an imaginary line shown in the drawing.

The wiring board 10 has a portion of the wiring 12 provided on the board front surface S1. In addition, in the present embodiment, an example is adopted in which the wiring 12 is provided inside the insulating substrate 11, not just on the board front surface S1. The wiring 12 includes a mounting land 13a as a portion provided on the board front surface S1 of the wiring board 10. The mounting land 13a is a portion of the wiring 12 that is exposed on the side of the board front surface S1. The mounting land 13a corresponds to a land. In FIG. 4, a portion of the wiring 12 to which the element terminal 21a is connected is a portion of the wiring 12 exposed on the board front surface S1 side, and can also be called a circuit mounting land.

As shown in FIG. 3, the wiring board 10 has fixing lands 13b for fixing the connector 30 (fixing member 32) which will be described later. The fixing lands 13b are provided on the board front surface S1. The fixing lands 13 b are made of the same material as the wiring 12. However, the fixing lands 13 b are electrically isolated from the wiring 12. The fixing member 32 is fixed to the fixing land 13b by soldering.

The fixing land 13b is provided around a cutout portion 14 in which a connector case 33, which will be described later, is disposed. In the present embodiment, as an example, the fixing lands 13b provided on both sides of the cutout portion 14 in the longitudinal direction are adopted. The fixing land 13b has, for example, a rectangular shape in a plan view in which a length in the longitudinal direction is shorter than a length in the lateral direction.

However, the fixing land 13b may have a longer longitudinal length in plan view in comparison with the above configuration. By increasing the length of the fixing land 13b in the longitudinal direction, the fixing strength with the fixing member 32 can be improved. According to the above configuration, the fixing land 13b can improve durability against stress applied when a mating connector is inserted into and removed from the connector 30. Hereinafter, this stress will also be referred to as insertion/removal stress.

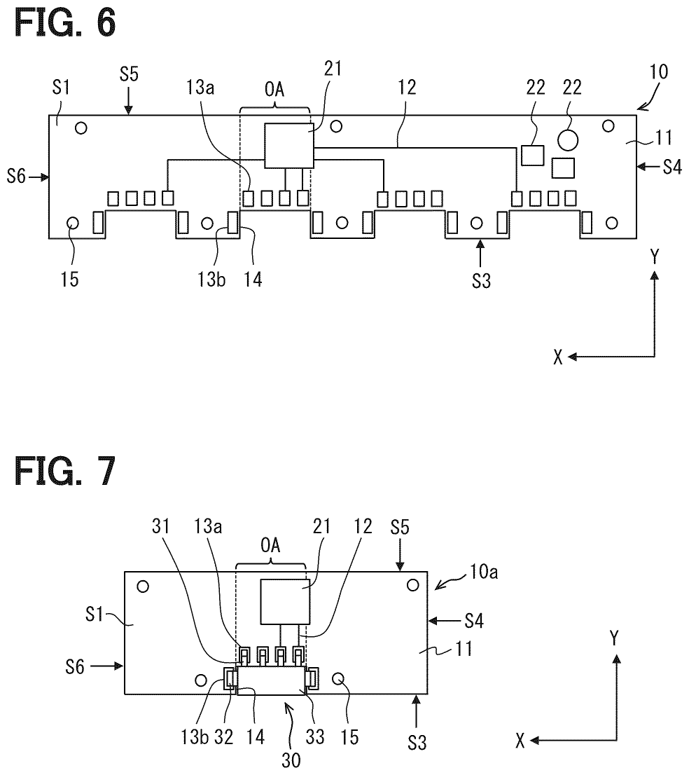

As shown in FIGS. 3, 4 and 6, the wiring board 10 has the cutout portion 14 recessed from the surrounding area on a part of the side surfaces S3 to S6. The cutout portion 14 is a portion where the connector 30 is disposed. More specifically, the cutout portion 14 is a portion in which a connector case 33, which is a part of the connector 30, is disposed. The cutout portion 14 can also be said to be a portion where the connector case 33 is attached. It can also be said that the connector case 33 is disposed in the space defined by the cutout portion 14.

Therefore, the cutout portion 14 can also be referred to as a connector placement portion or a placement recess portion. The cutout portion 14 can also be said to form a through hole extending from the board front surface S1 of the substrate to the board back surface S2 of the substrate on the long side surface S3. Furthermore, it can be said that the cutout portion 14 is formed by three continuous surfaces of the wiring board 10. The three surfaces are two opposing surfaces along the Y direction and a connecting surface that connects the two opposing surfaces along the X direction. The cutout portion 14 corresponds to a recess portion.

In the present embodiment, as an example, the wiring board 10 having the cutout portion 14 on the long side surface S3 is adopted. In other words, the cutout portion 14 is a portion recessed from the surrounding area of the cutout portion 14 on the long side surface S3. Furthermore, in the present embodiment, as an example, the wiring board 10 having the cutout portions 14 provided at four locations on the long side surface S3 is adopted. Therefore, when the long side surface S3 of the wiring board 10 is viewed from the Y direction, the recess portions that are the cutout portions 14 are provided at four locations spaced apart.

The cutout portion 14 has a shape corresponding to the outer shape of the connector case 33 in a plan view. In other words, the shape of the cutout portion 14 in the XY plane is similar to the shape of the connector case 33 in the XY plane. Moreover, the area of the cutout portion 14 in the XY plane is approximately the same as the area of the connector case 33 in the XY plane. In other words, the cutout portion 14 may have any size as long as the connector case 33 can be disposed therein.

However, the cutout portions 14 are not limited to the above configuration, and the cutout portions 14 may be provided on the side surfaces S4 to S6 other than the long side surface S3. In addition, in the present disclosure, the cutout portion 14 may be provided in only one location, or in two, three, five or more locations. Furthermore, the length of the cutout portion 14 in the lateral direction may be shorter than the length of the connector case 33 in the lateral direction. In this case, the connector case 33 protrudes from the long side surface S3 when disposed in the cutout portion 14.

As shown in FIG. 3, the wiring board 10 is provided with fixing holes 15. The fixing holes 15 are through holes for screwing the wiring board 10 to a base 41 which will be described later. That is, the wiring board 10 is fixed to the base 41 by screws. The fixing holes 15 are provided at positions that sandwich at least the cutout portion 14. In other words, it can be said that the wiring board 10 has the fixing holes 15 provided on both sides of the cutout portion 14 in the longitudinal direction. This can prevent insertion/removal stress from being transmitted to the wiring board 10. Therefore, the wiring board 10 can reduce stress on the battery monitoring IC 21, which will be described later. The fixing holes 15 correspond to the fixing portions.

In the present embodiment, an example is adopted in which the cutout portions 14 are provided at positions other than at positions that sandwich the cutout portion 14. Furthermore, the wiring board 10 may be fixed to the base 41 by a method other than screw fastening. Methods other than screw fastening include adhesive fastening, fitting fastening, thermal caulking, and even a method of fastening by pressing the base 41 and the cover 42 together.

Incidentally, as shown in FIG. 5, this embodiment employs the wiring board 10 that is warped so that the board front surface S1 side has a convex shape due to the difference in linear expansion coefficient between the insulating substrate 11 and the wiring 12. Furthermore, the wiring board 10 is more prone to warping due to the provision of the cutout portion 14 as described above. In other words, the wiring board 10 has a different length in the lateral direction due to the cutout portions 14. Therefore, the wiring board 10 is prone to warping at the portions where the length in the lateral direction is short. However, the present disclosure is not limited to this configuration, and may also be adopted for the wiring board 10 that is warped so that the board front surface S1 side has a concave shape.

The area having a short length in the lateral direction is referred to as an opposing area OA. The opposing area OA is an area adjacent to the cutout portion 14 in the lateral direction on the board front surface S1. The opposing area OA can also be said to be an area opposing the cutout portion 14 in the lateral direction in a plan view. The opposing area OA can also be said to be an area aligned with the cutout portion 14 on the board front surface S1. The opposing area OA can be said to be a part of the board front surface S1 in the opposing area in the lateral direction of the cutout portion 14. The longitudinal length of the opposing area OA coincides with the longitudinal length of the cutout portion 14. The opposing area OA corresponds to a narrow area.

As shown in FIGS. 3 and 4, the wiring board 10 has a plurality of circuit components 21 and 22 mounted on the board front surface S1. That is, the circuit components 21 and 22 are surface-mount type chips such as BGA or QFP. BGA is an abbreviation for Ball Grid Array. QFP is an abbreviation for Quad Flat Package.

The battery monitoring device 100 is implemented with a battery monitoring IC 21 and a circuit element 22 different from the battery monitoring IC 21 as circuit components. The circuit elements 22 are, for example, circuit components that configure a communication circuit, or circuit components that provide other functions.

The battery monitoring IC 21 is an IC chip having at least the function of monitoring the voltage of the battery module 200. In detail, the battery monitoring IC 21 acquires battery information from each battery cell that constitutes the battery module 200. The battery information includes at least the voltage information of each battery cell. The battery information may also include temperature information, current information, self-diagnosis information, etc. of each battery cell. The self-diagnosis information is, for example, information regarding the operation check of the battery monitoring device 100, that is, information regarding an abnormality or malfunction of the battery monitoring device 100. The battery monitoring IC 21 can also be referred to as a cell supervising circuit (CSC).

As shown in FIG. 4, the battery monitoring IC 21 includes an element terminal 21a. The element terminal 21a is connected to the wiring 12 by solder 16. The circuit element 22 is also connected to the wiring 12 in a similar manner. That is, each of the circuit components 21 and 22 is connected to a part of the wiring 12 via the solder 16. As a result, the circuit components 21 and 22 form a circuit together with the wiring 12.

In the present embodiment, the circuit components 21 and 22 connected to the wiring 12 by reflow soldering are adopted. Further, the connector 30, which will be described later, is also connected to the wiring 12 by reflow soldering. In the connector 30, the terminal 31 and the mounting land 13a, and the fixing member 32 and the fixing land 13b are connected by reflow soldering. The circuit components 21, 22 and the connector 30 are connected to the wiring 12 etc. in the same reflow soldering process.

As shown in FIG. 3, the battery monitoring IC 21 is mounted so that at least a portion of the battery monitoring IC 21 is disposed in the opposing area OA. As described above, the opposing area OA is a portion where the wiring board 10 is prone to warping. Moreover, the battery monitoring IC 21 is a chip larger than the other circuit elements 22. Furthermore, the battery monitoring IC 21 is a chip that is heavier than the other circuit elements 22.

Therefore, the battery monitoring device 100 suppresses (reduces) warping of the wiring board 10 due to the weight of the battery monitoring IC 21 by disposing a portion of the battery monitoring IC 21 in the opposing area OA. It can also be said that the battery monitoring device 100 can suppress warping of the wiring board 10 at the location where the battery monitoring IC 21 is mounted. It is preferable that the battery monitoring IC 21 is entirely disposed in the opposing area OA in the plan view. This makes it possible to further reduce the warping of the wiring board 10. Also, as an example, the battery monitoring device 100 is provided with the wiring board 10 that is warped so that the board front surface S1 side has a convex shape in a state where the warping is suppressed by the weight of the battery monitoring IC 21. However, the present disclosure is not only limited to the above example. The battery monitoring device 100 may include the wiring board 10 that is warped so that the board front surface S1 side has a concave shape in a state where the warping is suppressed by the weight of the battery monitoring IC 21. Furthermore, the battery monitoring device 100 may include a wiring board 10 having a flat board front surface S1 in a state where the warping is suppressed by the weight of the battery monitoring IC 21.

The battery monitoring device 100 can reduce the stress applied to the battery monitoring IC 21 by reducing the warping of the wiring board 10. Similarly, the battery monitoring device 100 can reduce the stress applied to a connection portion between the battery monitoring IC 21 and the wiring board 10. Furthermore, the battery monitoring device 100 can reduce mounting defects of the battery monitoring IC 21 caused by warping of the wiring board 10. The above-mentioned stress is a stress caused by warping of the wiring board 10, and is also called warping stress. The connection portion is the element terminal 21a, the solder 16 and the wiring 12.

Incidentally, when a warping stress from the wiring board 10 is applied to the battery monitoring IC 21, distortion may occur. As a result, the battery monitoring IC 21 has a problem in that the voltage monitoring accuracy decreases. In other words, the warping stress of the wiring board 10 significantly affects the monitoring accuracy of the battery monitoring IC 21. On the other hand, the requirements for monitoring accuracy of battery are extremely high in order to improve safety and extend driving range. Therefore, it may be possible to provide a reinforcing member for suppressing warping of the wiring board 10. However, the battery monitoring device 100 has a problem in that the reinforcing members increase costs.

In order to solve these problems, in the present disclosure, a portion of the battery monitoring IC 21 is arranged in the opposing area OA. As a result, the battery monitoring device 100 can suppress warping of the wiring board 10 as described above, and reduce the warping stress applied to the battery monitoring IC 21. Therefore, the battery monitoring device 100 can prevent a decrease in the accuracy of voltage monitoring due to the battery monitoring IC 21. In other words, the battery monitoring device 100 can accurately monitor voltage information, which is one piece of battery information to be transmitted to the vehicle control device.

Then, the vehicle control device controls the driving of the traction motor and the charging and discharging of the battery pack 300 via the power control unit based on the battery information. Therefore, the vehicle control device can perform control based on accurate voltage information. The battery monitoring device 100 can extend the vehicle's driving range while ensuring safety. Furthermore, the battery monitoring device 100 does not require reinforcing members or the like, which helps prevent costs from increasing.

In the present embodiment, as an example, the wiring board 10 is used in which more circuit components 21, 22 are mounted on the board front surface S1 than on the board back surface S2. According to this configuration, the insulation distance (space) between each of the circuit components 21, 22 and the base 41 or cover 42 only needs to be ensured on the board front surface S1 side. Therefore, the thickness of the battery monitoring device 100 in the Z direction can be reduced.

Furthermore, the wiring board 10 may have a convex shape on the board front surface S1 side, and may warp so that the apex of the convex shape is aligned with the center line CL. In particular, the wiring board 10 having a plurality of cutout portions 14 formed in the longitudinal direction is prone to such warping. Therefore, the battery monitoring device 100 may have the battery monitoring IC 21 disposed on the center line CL. This also makes it possible to suppress warping of the wiring board 10.

### Connector

The connector 30 is an external connection component for connecting the wiring board 10 to an external device provided outside the wiring board 10. The connector 30 electrically connects the wiring board 10 and at least the battery module 200. In other words, the battery monitoring device 100 includes at least one connector 30 that electrically connects the wiring board 10 and the battery module 200. Therefore, the battery monitoring device 100 may include a connector 30 that electrically connects the wiring board 10 to an external device other than the battery module 200. The battery module 200 is an example of an external device. The external device may include a vehicle control device and a power control unit.

As shown in FIG. 4 and other figures, the connector 30 has terminals 31 connected to the mounting lands 13a that are part of the wiring 12 provided on the board front surface S1, and a connector case 33 in which the terminals 31 are provided. Furthermore, the connector 30 has a fixing member 32. The connector 30 corresponds to a connector member. The fixing member 32 corresponds to a fixing terminal. The connector case 33 corresponds to a housing.

The terminal 31 is a conductive member whose main component is metal. The connector case 33 is an insulating member whose main component is resin. The fixing member 32 is made of the same material as the terminal 31. The terminals 31 and the fixing members 32 are provided in the connector case 33 by, for example, insert molding.

In the connector 30, a part of the terminal 31 is connected to the mounting land 13a by the solder 16. As described above, the mounting lands 13a are provided on the board front surface S1. In other words, the connector 30 is connected to a part of the wiring 12 on the surface of the wiring board 10 without the terminal 31 being inserted into the wiring board 10. Therefore, the connector 30 can be said to be a surface-mount type connector. However, the connector 30 is fixed to the wiring board 10 without the connector case 33 being disposed on the board front surface S1. This point will be described in detail later.

The connector case 33 has, for example, a box shape that is open in one direction. In other words, the connector case 33 has five walls. The connector case 33 has two opposing wall surfaces, a connector front surface S11 and a connector back surface S12. The connector back surface S12 is the surface opposite to the connector front surface S11. The connector back surface S12 corresponds to a bottom surface of the housing.

The connector case 33 has an insertion opening 34 surrounded by these walls. The insertion opening 34 is a portion into which the mating connector is inserted. Moreover, the connector case 33 is configured so that the mating connector inserted into the insertion opening 34 can be removed. The direction in which a mating connector is inserted into and removed from the connector 30 is along the Y direction.

The terminals 31 are provided on the connector case 33 so as to protrude from both sides of one wall portion. A part of the terminal 31 is disposed in the insertion opening 34. The wall portion on which the terminal 31 is provided is a portion that faces the connection surface when the connector case 33 is placed in the cutout portion 14.

The connector 30 is attached with at least a portion of the connector case 33 disposed in the cutout portion 14. In other words, a portion of the connector 30 between the connector front surface S11 and the connector back surface S12 of the connector case 33 is disposed in the cutout portion 14. Therefore, it can be said that the connector case 33 is not disposed on the board front surface S1.

In the present embodiment, as an example, the connector 30 is employed in which the connector back surface S12 is disposed at the same position as the board back surface S2 in the thickness direction of the wiring board 10. In other words, the connector case 33 does not protrude beyond the board back surface S2 in the Z direction, but protrudes toward the board front surface S1. According to the above configuration, the battery monitoring device 100 can be made smaller in size in the thickness direction than a configuration in which the connector case 33 is mounted on the board front surface S1 or the board back surface S2 of the wiring board 10. The plate thickness direction coincides with the Z direction.

As described above, the wiring board 10 needs to have an insulating distance from the cover 42 on the board front surface S1 side. In other words, in the battery monitoring device 100, the distance between the board front surface S1 and the cover 42 is greater than the distance between the board back surface S2 and the base 41. Therefore, when the battery monitoring device 100 includes the base 41 and the cover 42, even if the connector case 33 protrudes toward the board front surface S1, the size of the battery monitoring device 100 in the thickness direction is unlikely to increase. Therefore, the battery monitoring device 100 can be made smaller in size in the thickness direction than a configuration in which the connector case 33 protrudes from both the board front surface S1 and the board back surface S2.

However, the positional relationship between the connector 30 and the wiring board 10 is not limited to the above configuration. The present disclosure can also be adopted, for example, in a configuration in which the connector case 33 protrudes from both the board front surface S1 and the board back surface S2.

As shown in FIG. 3, the connector 30 has the fixing member 32 provided on a side wall of the connector case 33. The fixing member 32 is connected to the fixing land 13b as described above. The connector 30 is fixed to the wiring board 10 by connecting the fixing member 32 to the fixing land 13b while being placed in the cutout portion 14. In other words, the connector 30 is not fixed to the wiring board 10 by at least a portion of the connector case 33 being deformed by fitting or the like, but is fixed to the wiring board 10 by soldering.

This enables the battery monitoring device 100 to firmly fix the connector 30 to the wiring board 10. The battery monitoring device 100 can suppress the application of insertion/removal stress to the terminal 31 and the connection portion between the terminal 31 and the mounting land 13a. Furthermore, the battery monitoring device 100 can suppress board displacement (deformation) of the wiring board 10 caused by the insertion/removal stress, and suppress deterioration of the voltage monitoring accuracy of the battery monitoring IC 21.

It can also be said that the connector case 33 is disposed only in the cutout portion 14 in a plan view. In other words, the connector case 33 is not disposed in a location where the cutout portion 14 is not formed in a plan view.

### Housing

As shown in FIG. 2, the battery monitoring device 100 includes a base 41 and a cover 42 as a housing. The base 41 and the cover 42 are made primarily of a metal such as aluminum. The wiring board 10 is fixed to the base 41 as described above. The cover 42 is attached to the base 41 to form, together with the base 41, a accommodation space for accommodating the wiring board 10. The manner in which the base 41 and the cover 42 are fixed to each other is not particularly limited. The base 41 and the cover 42 may be made mainly of resin. Furthermore, one of the base 41 and the cover 42 may be made mainly of resin, and the other may be made mainly of metal.

The accommodation space accommodates not only the wiring board 10 but also the circuit components 21 and a part of the connector 30. The connector 30 is accommodated in the accommodation space such that the insertion opening 34 is exposed to the outside of the accommodation space. This allows the battery monitoring device 100 to be electrically connected to an external device via the connector 30. In this manner, in the battery monitoring device 100, the wiring board 10 and other components are covered by the base 41 and the cover 42. Therefore, the battery monitoring device 100 can prevent foreign matter from adhering to or colliding with the wiring board 10 or the like. Furthermore, the battery monitoring device 100 can suppress adverse electrical influences propagated from outside the accommodation space to the wiring board 10. In other words, the battery monitoring device 100 can ensure the insulation of the wiring board 10 on which the circuit components 21 and 22 are mounted.

### Placement Example of Battery Monitoring Device

As shown in FIG. 1, the battery monitoring device 100 is disposed between the battery modules 200 in the left-right direction LD. In the present embodiment, the forward direction FD coincides with the X direction, and the left-right direction LD coincides with the Z direction. Therefore, the wiring board 10 is disposed with its lateral direction aligned with the left-right direction LD and its longitudinal direction aligned with the forward direction FD, and is disposed between the multiple battery modules 200 disposed in the left-right direction LD.

The battery monitoring device 100 may be disposed between the battery modules 200 in the forward direction FD. Moreover, the battery monitoring device 100 may be disposed between the battery module 200 and the vehicle seat.

### Effect

As described above, in the battery monitoring device 100, the terminals 31 are connected to the mounting lands 13a provided on the board front surface S1 of the wiring board 10. In addition, in the battery monitoring device 100, at least a portion of the connector case 33 is disposed in the cutout portion 14 provided in the long side surface S3 of the wiring board 10. Therefore, the battery monitoring device 100 can be made smaller in size in the thickness direction of the wiring board 10. In other words, the battery monitoring device 100 can be made thinner in the thickness direction of the wiring board 10.

Furthermore, by arranging at least a portion of the battery monitoring IC 21 in the opposing area OA, the battery monitoring device 100 can achieve both a low profile and suppression of a decline in voltage monitoring accuracy due to warping of the wiring board 10. By connecting the fixing member 32 to the fixing land 13b, the battery monitoring device 100 can achieve both a low profile and suppression of a decline in voltage monitoring accuracy due to displacement of the wiring board 10.

Incidentally, the size of the battery pack 300 in the left-right direction LD is limited due to side impact protection requirements. However, as described above, the battery monitoring device 100 can be made thinner in the thickness direction of the wiring board 10. In the battery monitoring device 100, the thickness direction of the wiring board 10 coincides with the left-right direction LD. Therefore, the battery monitoring device 100 can prevent a reduction in the number of mounted battery modules 200 in the left-right direction LD. In other words, the battery monitoring device 100 can ensure the number of mounted battery modules 200 while satisfying the collision protection requirements. Furthermore, since the battery monitoring device 100 is disposed between the battery modules 200 in the left-right direction LD, it is possible to prevent the living space of the vehicle from becoming narrower.

Furthermore, as described above, the battery monitoring device 100 can be made low-profile in the thickness direction of the wiring board 10. Therefore, in a configuration in which the battery monitoring device 100 is disposed between the battery modules 200 in the front-rear direction of the vehicle, a reduction in the number of battery modules 200 mounted in the front-rear direction of the vehicle can be suppressed. Furthermore, in a configuration in which the battery monitoring device 100 is disposed between the battery module 200 and a vehicle seat, it is possible to prevent the living space of the vehicle from becoming narrower.

Furthermore, the battery monitoring device 100 does not require a reinforcing member for suppressing warping of the wiring board 10. Therefore, the battery monitoring device 100 can reduce costs. Furthermore, the battery monitoring device 100 can extend the driving range by reducing weight.

### First Modified Example

A wiring board 10a according to the first modified example will be described with reference to FIG. 7. The battery monitoring device 100 includes the wiring board 10a on which the cutout portion 14 is provided at only one location. In other words, the battery monitoring device 100 has only one connector 30. According to this configuration, the battery monitoring device 100 achieves the same effects as those described above.

Furthermore, the present embodiment employs the cutout portion 14 which is a hole formed by recessing a part of the long side surface S3 and reaching from the board front surface S1 to the board back surface S2. In other words, in the battery monitoring device 100, when the connector 30 is mounted on the wiring board 10, the wiring board 10 is not provided in the opposing area of the connector case 33 in the Z direction. However, the present disclosure is not only limited to the above example.

The battery monitoring device 100 can also employ a concave cutout portion 14 that does not reach from the board front surface S1 to the board back surface S2. In other words, the cutout portion 14 has an opening along the board front surface S1 and an opening along the long side surface S3, and is closed on the board back surface S2 side. In this case, in the battery monitoring device 100, with the connector 30 mounted on the wiring board 10, a part of the wiring board 10 is provided in an opposing area of the connector case 33 in the Z direction. Even with this configuration, the battery monitoring device 100 can be made smaller in size in the thickness direction. In addition, the battery monitoring device 100 can also place the connector case 33 in the cutout portion 14 in a state that the connector case 33 is in contact with a portion of the wiring board 10 provided in the opposing area in the Z direction. This makes it possible to improve the mounting strength of the connector 30 on the wiring board 10.

Although the present disclosure has been described in accordance with the embodiments, it is understood that the present disclosure is not limited to such embodiments or structures. The present disclosure encompasses various modifications and variations within the scope of equivalents. In addition, while various combinations and modes are described in the present disclosure, other combinations and modes including only one element, more elements, or less elements therein are also within the scope and spirit of the present disclosure.

What is claimed is:

1. A battery monitoring device for monitoring a state of a battery mounted on a vehicle, comprising:
a wiring board having a portion of a wiring provided on a first surface;
a circuit component surface-mounted on the first surface and connected to the wiring; and
a connector member for electrically connecting the wiring board and at least the battery, the connector member having a terminal connected to a land that is a part of the wiring provided on the first surface and a housing in which the terminal is provided; wherein
the wiring board has a cutout portion on a part of its side surface that is recessed from a surrounding area, and at least a part of the housing is disposed in the cutout portion.

2. The battery monitoring device according to claim 1, wherein
the connector member is arranged such that, in a thickness direction of the wiring board, a bottom surface of the housing is flush with a second surface opposite to the first surface of the wiring board.

3. The battery monitoring device according to claim 1, wherein
the wiring board has, as the side surface, a short side surface along a lateral direction of the first surface, and a long side surface on which the cutout portion is provided along a longitudinal direction of the first surface, and
at least a part of the circuit component is disposed in a narrow area adjacent to the cutout portion in the lateral direction on the first surface.

4. The battery monitoring device according to claim 3, wherein
the battery supplies power to an electric motor that drives the vehicle, and
the circuit component has a function of monitoring a voltage of the battery.

5. The battery monitoring device according to claim 3, wherein
the wiring board is warped so that a convex shape is formed on the first surface side.

6. The battery monitoring device according to claim 3, wherein
the circuit component and the connector member are connected to the wiring by reflow soldering.

7. The battery monitoring device according to claim 1, wherein
the wiring board has cutout portions formed in a plurality of locations on the side surface, and the housing is disposed in each cutout portion.

8. The battery monitoring device according to claim 1, further comprising,
a base to which the wiring board is fixed, and a cover attached to the base and forming an accommodation space for the wiring board together with the base, wherein
the wiring board is provided with a fixing portion for fixing to the base at positions that sandwich the cutout portion.

9. The battery monitoring device according to claim 1, wherein
in the wiring board, a lateral direction of the first surface is aligned along a left-right direction of the vehicle and a longitudinal direction of the first surface is aligned along a front-rear direction of the vehicle, and the wiring board is disposed between a plurality of batteries arranged in the left-right direction.

10. The battery monitoring device according to claim 1, wherein,
the wiring board is provided with a fixing land around the cutout portion on the first surface, and
the connector member has a fixing terminal provided on a side wall of the housing, and the fixing terminal is connected to the fixing land.
